(19) United States
(12) Patent Application Publication
(10) Pub. No.: US 2005/0116729 A1
(43) Pub. Date: Jun. 2, 2005

(54) Method and device for testing or calibrating a pressure sensor on a wafer

(76) Inventors: Oliver Koester, Hilden (DE); Johann Slotkowski, Herdecke (DE)

Correspondence Address: GLENN PATENT GROUP, 3475 EDISON WAY, SUITE L, MENLO PARK, CA, 94025, US

(21) Appl. No.: 10/481,005

(22) Filed: Dec. 11, 2003

Related U.S. Application Data
(63) Continuation of application No. PCT/EP02/06350, filed on Jun. 10, 2002.

(30) Foreign Application Priority Data
Jun. 11, 2001 (DE) 10128235.4

(51) Int. Cl. G01R 31/02

(52) U.S. Cl. 324/754

(57) ABSTRACT

A method is provided for testing or calibrating a pressure sensor of a plurality of pressure sensors formed in a wafer, wherein the pressure sensor has a pressure-sensitive portion and a signal output. The method includes a step of connecting the pressure-sensitive portion of the pressure sensor to a fluid line in a pressure-tight way, a step of applying a predetermined pressure to the pressure-sensitive portion of the pressure sensor via the fluid line and a step of receiving a signal from the signal output of the pressure sensor.

### CROSS-REFERENCE TO RELATED APPLICATION

This application is a continuation of copending International Application No. PCT/EP02/06350, filed on Jun. 10, 2002, which designated the United States and was not published in English.

### BACKGROUND OF THE INVENTION

1. Field of the Invention

The present invention relates to a method and a device for testing or calibrating a pressure sensor on a wafer.

2. Description of the Related Art

Microelectronic circuits formed in or on a wafer are usually tested before dicing the wafer and housing the individual circuits. These tests are performed by automatic wafer probers or wafer testers. A wafer prober includes a handling system or handling means taking one individual wafer from a storage unit (rack) and passing it to the actual prober. The wafer is placed on a moveable carrier plate, the so-called chuck, and is fixed there by suction or electrostatically or with the help of an adhesive layer. The prober performs an exact positioning of the wafer to be tested in all three space directions. After the positioning of the wafer to be tested has been performed, exactly one respective integrated circuit of the wafer is put below an immovably arranged probe card. The probe card has a plurality of wolfram pins or needles, the arrangement of which exactly corresponds to the geometry of the microscopic pads on the integrated circuit. For contacting the integrated circuit, the chuck is moved in height or the z direction perpendicularly to the wafer plane until the probes of the probe card touch the pads and thus form electrically conductive connections to them. Electrical signals are supplied to the integrated circuit or electrical signals produced by the integrated circuit are tapped via macroscopic taps associated to the probes of the probe card and connected to them in an electrically conductive way.

A probe card can contact a respective or several integrated circuits at one time. For sequentially contacting and testing all the integrated circuits, the wafer with the chuck is repeatedly moved by predetermined distances parallel to the wafer plane and driven to the probes of the probe card. Since the exact positions of all the integrated circuits on a wafer are known, a single positioning of the wafer is thus sufficient. The wafer prober is connected to a computer or a workstation of a testing system, respectively, via a serial interface so that a test program executed by the testing system or the computer can communicate to the wafer prober.

If the integrated circuit includes a pressure sensor, only a test of electrical functions and functionalities of the integrated circuit is possible with the wafer prober described above. After the test, the wafer is diced and electrically functioning integrated circuits are housed, i.e. inserted or potted in a case. Subsequently, a test and a calibration, if suitable, of the diced and housed pressure sensors are performed.

This procedure has the disadvantage that defect pressure sensors are housed, too, since their defect will only be recognized after dicing and housing. In addition, testing the diced and housed pressure sensors is complicated and expensive since every single pressure sensor must be handled, positioned and contacted. Thus, cost reasons prevent an application of pressure sensors in a number of products. In some products, the calibration described cannot be performed after dicing and housing for technological reasons. A further disadvantage is that, for storing or programming calibration coefficients or calibration parameters into the pressure sensor or the integrated circuit of it or an integrated memory element (such as, for example, an EEPROM), the case may have to have one or several additional contacts which are only used once, that is when calibrating the pressure sensor, which, however, increases the production cost and increases the danger of damage or destruction of it during the entire life time of the pressure sensor.

### SUMMARY OF THE INVENTION

It is the object of the present invention to provide an improved test or calibration method for a pressure sensor, a method for manufacturing a pressure sensor and a device simplifying testing and calibrating a pressure sensor.

In accordance with a first aspect, the present invention provides a method for testing or calibrating a pressure sensor of a plurality of pressure sensors formed in a wafer, wherein the pressure sensor has a pressure-sensitive portion and a signal output, wherein the signal output includes pads, and wherein the pads and the pressure-sensitive portion are arranged on a surface of the wafer, including the following steps: providing a probe card having probes with probe tips, wherein the probe card has an upper side and a lower side, wherein the lower side of the probe card is directed towards the surface of the wafer, wherein the probes are arranged on the lower side of the probe card, and wherein a sealing lip surrounding the probe tips is further attached on the lower side of the probe card; connecting the pressure-sensitive portion of the pressure sensor to the fluid line in a pressure-tight way by contacting the sealing lip with the surface of the wafer, wherein the probe tips are further electrically connected to the pads; applying a predetermined pressure to the pressure-sensitive portion of the pressure sensor via the fluid line; and receiving a signal from the signal output of the pressure sensor via the probes of the probe card.

In accordance with a second aspect, the present invention provides a method for manufacturing a pressure sensor element, including the following steps: providing a wafer having a plurality of pressure sensors, wherein each pressure sensor has a pressure-sensitive portion and a signal output; applying a method to one of the plurality of pressure sensors, the method being for testing or calibrating a pressure sensor of a plurality of pressure sensors formed in a wafer, wherein the pressure sensor has a pressure-sensitive portion and a signal output, wherein the signal output includes pads, and wherein the pads and the pressure-sensitive portion are arranged on a surface of the wafer, the method including the following steps: providing a probe card having probes with probe tips, wherein the probe card has an upper side and a lower side, wherein the lower side of the probe card is directed towards the surface of the wafer, wherein the probes are arranged on the lower side of the probe card, and wherein a sealing lip surrounding the probe tips is further attached on the lower side of the probe card, connecting the pressure-sensitive portion of the pressure sensor to the fluid line in a pressure-tight way by contacting the sealing lip with the surface of the wafer, wherein the probe tips are further electrically connected to the pads, applying a predetermined pressure to the pressure-sensitive portion of the pressure sensor via the fluid line, and receiving a signal from the signal output of the pressure sensor via the probes of the probe card; dicing the wafer after applying the method to obtain the diced pressure sensor; and housing the diced pressure sensor to obtain the pressure sensor element.

In accordance with a third aspect, the present invention provides a device for applying a certain pressure to a pressure sensor of a plurality of pressure sensors formed in a wafer and for receiving a signal from a signal output, having pads, of the pressure sensor, wherein the pressure sensor has a pressure-sensitive portion, and wherein the pads and the pressure-sensitive portion are arranged on a surface of the wafer, including means for providing a probe card having probes with probe tips, wherein the probe card has an upper side and a lower side, wherein the lower side of the probe card is directed towards the surface of the wafer, wherein the probes are arranged on the lower side of the probe card, and wherein a sealing lip surrounding the probe tips is further arranged on the lower side of the probe card; means for connecting the pressure-sensitive portion to the fluid line provided for supplying the predetermined pressure in a pressure-tight way by contacting the sealing lip with the surface of the wafer, wherein the probe tips are further electrically connected to the pads; and means for receiving the signal from the signal output of the pressure sensor via the probes of the probe card.

In accordance with a fourth aspect, the present invention provides a probe card for testing or calibrating a pressure sensor of a plurality of pressure sensors formed in a wafer, wherein the pressure sensor has a pressure-sensitive portion and a signal output, wherein the signal output includes pads, and wherein the pads and the pressure-sensitive portion are arranged on a surface of the wafer, including: a probe card body having an upper side and a lower side, wherein the lower side of the probe card is to be directed towards the upper side of the wafer when the pressure sensor is tested of calibrated; probes with probe tips arranged on the lower side of the probe card; and a sealing lip attached to the lower side of the probe card such that it surrounds the probe tips.

The present invention is based on the finding of testing or calibrating pressure sensors, in particular surface-micromechanical absolute pressure sensors, and in particular pressure sensors provided for a negative pressure range, still in a wafer, i.e. before dicing it. For this, a pressure-sensitive portion of the pressure sensor is connected to a fluid line for example by means of a sealing lip via which one or subsequently several predetermined pressures can be applied to the pressure-sensitive portion of the pressure sensor. Preferably, simultaneously to or after applying a pressure, a signal produced by the pressure sensor responsive to the pressure on a signal output is received. For this, the test or calibration is preferably performed by means of an automatic wafer tester with a probe card, wherein the sealing lip is arranged between the probe card and a surface of the wafer where the pressure-sensitive portion of the pressure sensor is arranged. This sealing lip surrounds the pressure-sensitive portion, the probes of the probe card and the pads of the pressure sensor laterally for example in the form of a circle or of a rectangle and seals the gap between the surface of the wafer on the one hand and the probe card in which the pressure-sensitive portion of the pressure sensor is arranged on the other hand in a pressure-tight way relative to the environment. Preferably, a standard wafer tester is modified and particularly provided with the sealing lip below the probe card.

An opening often present in conventional probe cards above the probe tips may be closed in a pressure-tight way by means of a cap preferably comprising a transparent material, such as, for example, PMMA (poly methyl methacrylate). A fluid line thus connects the completely pressure-tight surrounded cavity between the surface of the wafer, the probe card and the cap to a pressure system producing the one or several predetermined pressures.

It is an advantage of the present invention that the pressure sensors can be tested or calibrated on the wafer not yet diced. This can take place simultaneously to a test of the electrical features of the integrated circuit or its functionality. Repeated handling, positioning and contacting the diced and housed pressure sensors are thus not required. Defect pressure sensors will not be housed since they have already been identified. Corresponding to the resulting simplification and shortening of the manufacturing process in the area of testing and calibrating, considerable cost advantages result which, as far as economics is concerned, enable the usage of integrated pressure sensors in many products. In addition, the present invention makes possible the usage of integrated pressure sensors in products in which testing or calibrating cannot be performed after dicing for technological reasons. The housed pressure sensor and its housing, respectively, need not comprise contacts for transferring calibration coefficients into an integrated memory element (such as, for example, an EEPROM). Thus, size and production cost of the casing can be produced and the risk of a future damage of these contacts can be avoided. A further advantage of the present invention is that it can be implemented by modifying a conventional wafer tester. The present invention thus only produces small investment cost.

A preferred field of application of the present invention is manufacturing absolute pressure sensors, in particular in a negative pressure range between 0 and 1 bar and, in particular, surface-micromechanical absolute pressure sensors in high numbers and, in particular, for fields of application in which the customer, after inserting the absolute pressure sensor into an entire system, does not have the possibility for calibrating the sensor.

### BRIEF DESCRIPTION OF THE DRAWINGS

Preferred embodiments of the present invention will be detailed subsequently referring to the appended drawings, in which:

FIG. 1 is a schematic illustration of a pressure sensor testing system according to the present invention;

FIG. 2 is a schematic sectional illustration of an inventive device;

FIGS. 3A and 3B show a schematic top view of a wafer and a schematic sectional illustration of a sealing lip according to the present invention; and

FIGS. 4A and 4b show a schematic top view and a schematic sectional illustration of a cap according to the present invention.

### DESCRIPTION OF THE PREFERRED EMBODIMENTS

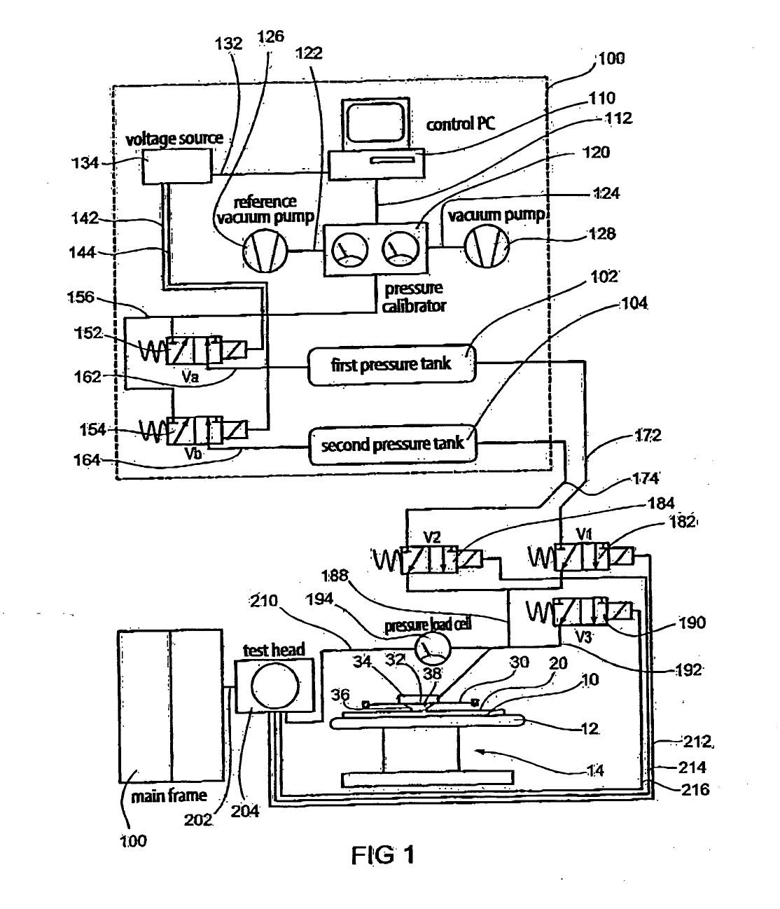

In FIG. 1, a schematic illustration of a testing system according to a preferred embodiment of the present invention is shown. A wafer 10 is held by a wafer carrier or chuck 12 of a prober 14 by means of a negative pressure, electrostatically or by means of an adhesive layer and is positioned in all three space directions. On a surface 20 of the wafer 10, a plurality of non-illustrated pressure sensors preferably having the same setup among one another and arranged in a regular raster are arranged. Each pressure sensor includes a pressure-sensitive portion, a mechanical-electrical transducer and a signal output.

In the case of a piezoelectric pressure sensor, the mechanical-electrical transducer is a solid body containing a piezo-effect, such as, for example, a piezoelectric crystal having a surface representing the pressure-sensitive portion of the pressure sensor.

In the case of a capacitive pressure sensor, the mechanical-electrical transducer is a capacitor, the capacitor plate of which is a diaphragm deformable by a pressure, the surface of which represents the pressure-sensitive portion of the pressure sensor. The signal output of the pressure sensor has a plurality of pads via which an electrical power, an electrical voltage or another electrical signal can be fed to the pressure sensor, if required, and via which a signal produced or influenced by the pressure sensor can be tapped.

In addition, each pressure sensor can have an integrated circuit connected between the mechanical-electrical transducer and the pads for generating, processing or transducing electrical signals. If the above-mentioned capacitive pressure sensor is provided for being supplied with a direct voltage, the integrated circuit will preferably comprise an oscillator based on a comparator. The capacitor including the diaphragm is charged by a predetermined current, wherein the comparator compares the voltage at the capacitor to a reference voltage. As soon as the voltage at the capacitor reaches the reference voltage, switching from the charging process to a discharging process takes place. This discharging process is, controlled by a second comparator, either disrupted when dropping below a second reference voltage or a complete discharge is performed via a short-circuit. Charging and discharging processes are repeated cyclically, wherein a sequence of zeros and ones is produced. The period Δt of the charging/discharging cycle and the sequence of zeros and ones, respectively, due to the pressure-dependence of the capacity of the capacitor, are a function of the pressure. Alternatively or in addition to a digital output signal, the integrated circuit can also produce an analog output signal.

Alternatively, the integrated circuit of the capacitive pressure sensor comprises a resonator in which the capacitor including the diaphragm is integrated as a device determining the characteristic frequency. In this case, the pressure sensor may additionally comprise a transducer transducing the resonance frequency of the oscillator influenced by the pressure into an analog or digital signal.

In the above-mentioned case of the pressure sensor with a piezoelectric mechanical-electrical transducer, the integrated circuit is preferably provided for amplifying, impedance-transducing or digitalizing the output signal of the piezoelectric sensor. Preferably, the integrated circuit further has an analog or digital memory for storing one or several calibration coefficients with the help of which it produces a calibrated output signal of the pressure sensor.

A probe card 30 having a plurality of probes is arranged opposite the surface 20 of the wafer 10. The lateral arrangement of the probes and the probe tips, respectively, corresponds to the lateral arrangement of the pads of a pressure sensor. In a corresponding relative space arrangement of the wafer 10 and the probe card 30, the probes of the probe card 30 contact the pads of one of the pressure sensors of the wafer 10 so that via the probes an electrical power or an electrical signal can be fed to the pressure sensor an electrical signal produced or influenced by the pressure sensor can be tapped.

The probe card 30 has an opening 32 below which the tips of the non-illustrated probes are arranged. Above the opening 32 there is a cap 34 connected to the probe card 30 in a pressure-tight way. Between the probe card 30 and the surface 20 of the wafer 10, there is a sealing lip 36 surrounding the opening 32 and the probes and their tips, respectively, in a lateral direction for example in the form of a circle or a rectangle. In a relative space arrangement of the probe card 30 and the wafer 10 in which the probes of the probe card 30 contact the pads of a pressure sensor on the surface 20 of the wafer 10, the sealing lip 36 forms a pressure-tight connection of the probe card 30 to the surface 20 of the wafer 10 so that a cavity 38 sealed relative to the environment in a pressure-tight way is formed between the cap 34, the probe card 30, the sealing lip 36 and the surface 20 of the wafer 10. In particular the pressure-sensitive portion of the pressure sensor is arranged in this cavity 38.

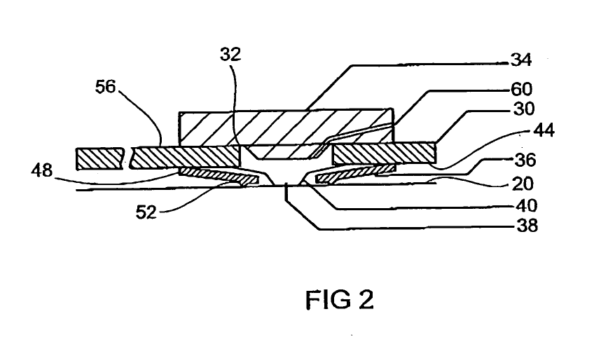

Before other structures and functional elements illustrated in FIG. 1 are discussed, the cavity 38, the sealing lip 36 and the cap 34 will first be explained in greater detail referring to FIG. 2, 3A, 3B, 4A and 4B. FIG. 2 shows an enlargement of a section of FIG. 1 in which the cavity 38 is illustrated in a cross section resulting when, by a corresponding relative space arrangement of the probe card 30 and the wafer 10 and its surface 20, respectively, probes 40 of the probe card 30 touch the non-illustrated pads of the pressure sensor on the surface 20 of the wafer 10 and contact them. The sealing lip 36, such as, for example, a soft silicone lip, is arranged on the lower side 44 of the probe card 30, wherein the exterior border 48 of the sealing lip is, for example, connected to the lower side 44 of the probe card 30 in a pressure-tight way by gluing.

The sealing lip 36 approximately has the form of a cover area of a flat truncated cone or of a flat truncated pyramid. Near its inner edge 50, the sealing lip 36 comprises a circulating border 52 directed to the surface 20 of the wafer 10, touching the surface 20 and forming a pressure-tight connection with it.

The cap 34 is arranged on an upper side 56 of the probe card 30 and, for example by means of gluing, connected to the probe card 30 so that it closes the opening 32 of the probe card 30 in a pressure-tight way. A bore or venting channel 60 connects the miniature pressure chamber or vacuum chamber or cavity 38 between the cap 34, the probe card 30, the sealing lip 36 and the surface 20 of the wafer 10 to a pressure system illustrated below referring to FIG. 1 for setting a predetermined pressure in the cavity 38.

As can be seen from FIG. 2, construction and setup of the sealing lip 36 are simplified for geometrical reasons when the probes 40 have a large as possible angle to the lower side 44 of the probe card 30. A preferred value of the angle between the probes 40 and the lower side 44 of the probe card 30, with which the present invention has been tested successfully, is 10 degrees.

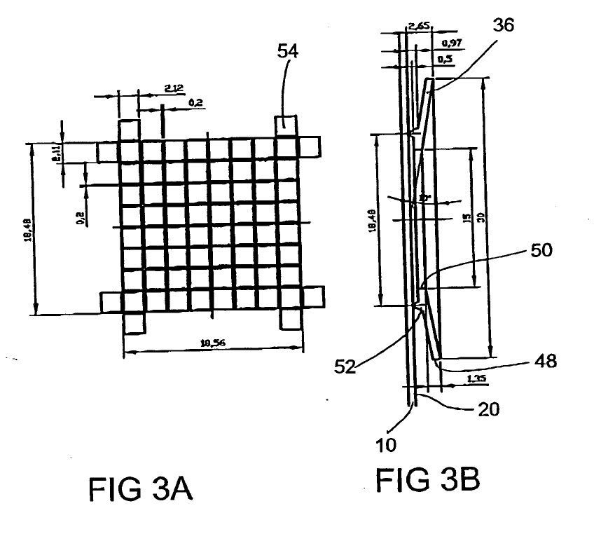

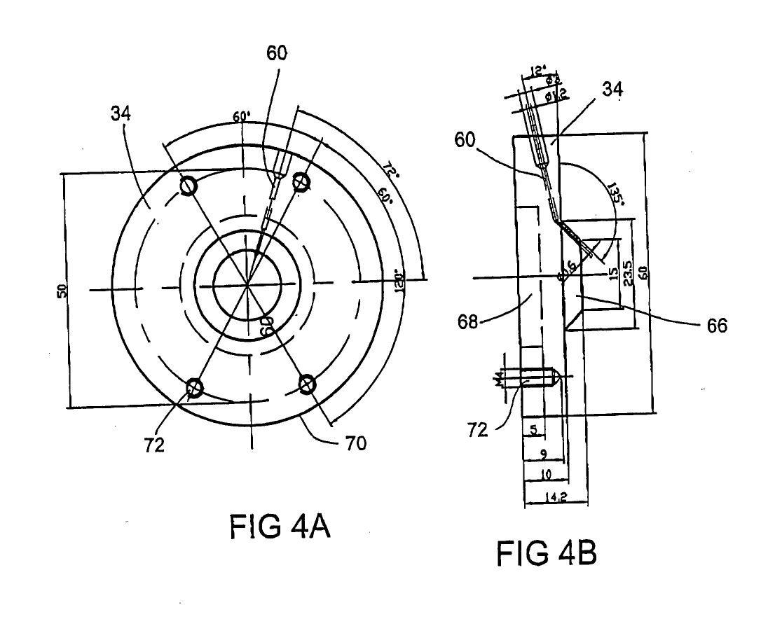

FIG. 3A is a schematic top view of a plurality of pressure sensors on a surface 20 of a wafer 10, for the manufacturing of which the present invention can be employed. In FIG. 3A, like in the following FIGS. 3B, 4A and 4B, some typical dimensions, which are, however, only indicated exemplarily, are indicated. The individual pressure sensors 54 have a length of 2.12 mm and a width of 2.11 mm and are arranged in an approximately square raster having a mutual pitch of 0.2 mm on the surface 20 of the wafer 10. Each pressure sensor 54 has a pressure-sensitive portion, pads for electric contacting and, preferably, an integrated circuit.

FIG. 3B is a schematic illustration of the sealing lip 36 in a section perpendicularly to the surface 20 of the wafer 10. In this embodiment, the sealing lip 36 is provided to surround 64 of the pressure sensors 54 illustrated in FIG. 3A. When the probe card 30 has probes 40 for simultaneously contacting all the pads of all the 64 pressure sensors 54 laterally surrounded by the sealing lip 36, these 64 pressure sensors can be tested or calibrated simultaneously.

The exterior border 48 of the sealing lip 36 laterally preferably has the form of a circle having a diameter of 30 mm, the interior border 50 of the sealing lip 36 laterally preferably has the form of a circle having a diameter of 15 mm. Somewhat outside the interior border 50, the sealing lip 36 has an edge 52 laterally approximately having the form of a square having a side length of 18.48 mm and 18.56 mm and thus, as has been described above, exactly surrounding 64 pressure sensors. The edge 52 compared to the inner border projects vertically 50 by 0.5 mm. The angle by which the sealing lip 36 deviates from a plane is 10°.

FIGS. 4A and 4B, in a schematic top view and a schematic sectional illustration, respectively, show the cap 34. FIG. 4B thus shows a section perpendicularly to the surface 20 of the wafer 10. The cap 34 is basically axially symmetric. Its exterior diameter is 60 mm. In the middle of the surface 64 facing the probe card 30, the cap 34 has a nose or projection 66 projecting into the opening 32 of the probe card 30. This projection 66 decreases the volume of the cavity 38, whereby setting a predetermined pressure in the cavity 38 is accelerated. Apart from the projection 66, the cap 34 has the form of a circular disc having two plane parallel surfaces, a thickness of 10 mm and a circular 5 mm deep recess 68 compared to the projection 66.

The cap 34 further comprises the bore or venting channel 60 via which pressure compensation takes place between the cavity 38 and the other pressure system described below referring to FIG. 1. The venting channel 60 ends in the area of the projection 66.

It can also be seen that the cap 34, close to its exterior circumference 70, has fixing bores 72 having one or several cut-in threads for mechanically fixing the cap 34 on a special device for mechanical stabilization. This device for mechanical stabilization is required since otherwise even a small negative or positive pressure in the cavity 38 causes deformation or bending of the probe card usually consisting of an FR4 board. A negative pressure results in a decrease in the distance between probe card and wafer. This decrease in the distance has the effect that the tips of the probes on the surface 20 of the wafer 10 are shifted that much that they leave the pads and damage the surrounding areas of the chip surface. In order to prevent this, probe card 30 and cap 34 are mechanically stabilized by the mentioned device not illustrated in the Figures.

The cap 34 is preferably formed of a transparent material, such as, for example, acrylic plastic or acrylic glass or PMMA (poly methyl methacrylate), respectively. For adjusting purposes, it is possible to look at the IC or pressure sensor to be detected through the cap 34 by means of a microscope or a camera part.

In the following, the pressure system with which the cavity 38 is connected via the venting channel 60 and by means of which predetermined pressures p1, p2, p3 in the cavity 38 are set will be discussed in greater derail referring to FIG. 1. A pressure providing system 100 provides two different predetermined pressures p1, p2 via pressure tanks 102, 104, wherein the pressures, controlled by means described below, can be applied to the cavity 38 in an alternating way. A control PC on which control software or a control program is executed, is connected to a pressure calibrator 120 via a data bus 112, such as, for example, a GPIP bus. The pressure calibrator 120 is connected to a reference vacuum pump 126 and a vacuum pump 128 via vacuum lines 122, 124. Controlled by the control PC 110, the pressure calibrator 120 alternatingly produces the two pressures p1, p2 to be applied to the cavity 38 and thus the pressure-sensitive portion of the pressure sensor to be tested or to be calibrated.

The control PC 110 is further, via a data bus 132 again preferably being a GPIP bus, connected to a voltage source 134 for generating two voltages. These two voltages are applied to magnetic control valves Va 152 and Vb 154 via control lines 142, 144 to open and close them. The magnetic control valves Va 152 and Vb 154 are, on the pressure input side, connected to the pressure calibrator 120 via a branched vacuum line 156. On the pressure output side, the magnetic control valve Va 152 is connected to the first pressure tank 102 via a vacuum line 162 and the magnetic control valve Vb 154 is connected to the second pressure tank 104 via a vacuum line 164.

The pressure providing system 100, as a self-contained system, independently of further components of the pressure system described below, provides two predetermined pressures p1, p2 in the pressure tanks 102, 104. For this, the control PC or the control program executed on it controls the pressure calibrator 120 and the magnetic control valves Va 152 and Vb 154 via the data busses 112, 132 and the voltage source 134. The pressure calibrator 120 alternatingly produces the first predetermined pressure p1 to be provided in the first pressure tank 102, wherein, at the same time, only the first pressure tank 102 is connected to the pressure calibrator 120 by an open magnetic control valve Vb 152 and a closed magnetic control valve Vb 154 and the second predetermined pressure p2 to be provided in the second pressure tank 104, wherein only the second pressure tank 104 is connected to the pressure calibrator 120 via a closed magnetic control valve Va 152 and an open magnetic control valve Vb 154.

The pressure tanks 102, 104 are connected to one magnetic control valve V1 182 or V2 184 each via vacuum lines 172, 174. The magnetic control valves V1 182 and V2 184 are also, in parallel to a magnetic control valve V3 190, connected to a pressure load or pressure measurement cell 194 via a multiple branched vacuum line 188 and connected to the cavity 38 via the venting channel 60. The magnetic control valve V3 190 is also connected to the surrounding atmosphere.

The magnetic control valves V1 182, V2 184 and V3 190, in FIG. 1, are illustrated as 3-way valves which are, however, only used as 2-way valves and the respective third input/output of which is closed continually. The reason for the usage of 3-way valves as 2-way valves is the small selection of pneumatic valves suitable for the usage in a negative pressure range.

A main frame 200 controlling testing and/or calibrating the pressure sensors is connected to a test head 204 via an interface 202, preferably a TH-MF interface. The test head 204 receives a pressure load signal from the pressure load cell 194 via the control line 210 and transmits control signals for the magnetic control valves V1 182, V2 184 and V3 190 via control lines 212, 214, 216. A test program executing on the main frame 200 can thus control the pressure applying in the cavity 38 and thus the pressure-sensitive section of the pressure sensor to be tested or to be calibrated via the test head 204 and by means of the magnetic control valves V1 182, V2 184 and V3 190.

In an output position, the valves V1 182 and V2 184 are closed and the valve V3 190 is open. In this case, the system, in particular the cavity 38, is vented and ambient pressure p3 is present. If the magnetic control valves V3 190 and V2 184 are closed and the magnetic control valve V1 182 is open, there is a fluid communication between the first pressure tank 102 and the cavity 38. The first predetermined pressure p1 provided in the first pressure tank forms in the cavity 38. If the magnetic control valves V3 190 and V1 182 are closed and the magnetic control valve V2 184 is open, there is a fluid communication between the second pressure tank 104 and the cavity 38. Consequently the second predetermined pressure p2 provided in the second pressure tank 104 forms in the cavity 38. As soon as the main frame 200 receives a pressure load signal from the pressure load cell 194 via the test head 204, the signal indicating that a pressure corresponding to the position of the valves V1 182, V2 184 and V3 190, that is one of the predetermined pressures p1, p2 or ambient pressure p2, has formed in the cavity 38, a test program routine is started. With the help of the test program routine, the pressure sensor and the integrated circuit are tested and the pressure analog sensor data or the digital or analog output signals of the pressure sensor representing the pressure detected by the pressure sensor are read out.

The calibration of the pressure sensor preferably takes place as is provided by the pressure system described above, at at least two different temperatures T1, T2 and at at least three different pressures p1, p2, p3 per temperature T1, T2 set. From the measurement data obtained in this way, individual calibration coefficients for the pressure sensor to be calibrated are calculated subsequently and, if this is provided for the pressure sensor, stored in an integrated memory of the pressure sensor. If the pressure sensor is only tested, it will be checked whether the deviations of the measurement values determined by the pressure sensor from the respective actually applying pressures p1, p2, p3 are within allowable limits or whether established calibration coefficients are within a predetermined range. Pressure sensors not satisfying these conditions will not be housed after subsequent dicing, but thrown away.

Since heating or cooling down the chuck or wafer carrier 12 and the wafer 10 takes place relatively slowly and takes a relatively long time, all the pressure sensors on a wafer are preferably measured at first at a fixedly set first predetermined temperature T1. Measurement data representing the functionality of the integrated circuit of the pressure sensor and the pressure measurement values of the pressure sensor for all the three predetermined pressures p1, p2, p3 are stored in a file. Subsequently, the wafer carrier 12 and the wafer 10 or all the wafers of the rack, respectively, are heated to a second temperature T2 and for all the pressure sensors not having been detected as defect in the first pass at the first predetermined temperature T1, the pressure measurement signals are detected again at the three pressures p1, p2, p3. In this second pass, a calibration routine is started by the test program directly after detecting the pressure measurement signals of a pressure sensor. The calibration routine determines individual calibration coefficients for the respective pressure sensor from the measurement data for the first predetermined temperature T1 stored in the file and the measurement data for the second predetermined temperature T2 and, if suitable, stores them in a memory of the integrated circuit of the pressure sensor provided for the calibration coefficients.

Depending on the physical measuring principle of the pressure sensor and the requirements posed by the application for which the pressure sensor is provided, calibration, due to measurements, can take place at only one or more than two temperatures as well as one, two or four or more pressures. Thus, the probe card 30 can contact only one respective individual pressure sensor or a plurality of pressure sensors at the same time. If the sealing lip 36 also surrounds this plurality of simultaneously contacted pressure sensors so that the predetermined pressure p1, p2 or ambient pressure p3 is applied simultaneously to all the contacted pressure sensors or their pressure-sensitive portions, respectively, all the contacted pressure sensors can be calibrated simultaneously.

If the probe card 30 and the sealing lip 36 do not contact or surround all the pressure sensors of the wafer 10 simultaneously, the wafer 10, after measuring, testing or calibrating a group of pressure sensors, will be moved away a little from the probe card 30, so that the probes 40 do not touch the pads of the pressure sensors anymore and the edge 52 of the sealing lip 36 does no longer touch the surface 20 of the wafer 10. The wafer 10 is then moved in a lateral direction by a distance corresponding to the raster measure with which the pressure sensors are arranged on the surface 20 of the wafer or to a multiple of it. Subsequently, the wafer 10 with the wafer carrier 12 is moved again in the direction of the probe card 30 so that the probes 40 contact the pads of the pressure sensors on the surface 20 of the wafer 10 and the edge 52 of the sealing lip 36 completely contacts the surface 20 of the wafer 10. Subsequently, one or several pressure sensors not having been measured, tested or calibrated so far are measured, tested or calibrated, respectively.

The pressure providing system 100 described above is provided for producing negative pressures or pressures smaller than ambient pressure. The present invention is, however, also usable for pressure sensors and their calibration in a positive pressure range, wherein a corresponding pressure could be provided to only the pressure calibrator by a compressor or a positive pressure pump, a pressure gas bottle or the like. In addition, an expansion of the pressure providing system 100 to more than two pressures which differ from ambient pressure is possible easily.

For testing or calibrating pressure sensors for other gases than air or for liquids, corresponding pumps 126, 128, valves 152, 154, 182, 184, 190, pressure tanks 102, 104, fluid lines 112, 132, 156, 162, 164, 172, 174, 188, 192, a corresponding pressure load cell 194 and a corresponding pressure calibrator 120 are used.

The pressure load cell 194 is either, as it is illustrated in FIG. 1, connected to the magnetic control valve V3 190 and the cavity 38 via a branched vacuum line 192 or connected directly to the cavity 38 via a separate vacuum 10 line or arranged in it, as has already been discussed referring to FIG. 4.

In the situation illustrated in FIGS. 1 and 2, the pressure sensor includes a pressure-sensitive portion on the surface 20 of the wafer 10 arranged between the pads contacted by the contact probes 40. Although this corresponds to a common arrangement of pads on an integrated circuit or chip, respectively, the pressure-sensitive portion of each pressure sensor can also be arranged next to the pads. In this case, the contact probes 40 of the probe card 30 can be arranged outside the sealing lip 36. Differing from the embodiment illustrated in FIGS. 1 and 2, the pressure sensor may have an optical signal output and/or an optical power input. In this case, an optical interface, apart from a (smaller) number of probes 40 or instead of the probes 40, respectively, is required to test the pressure sensors on the surface 20 of the wafer 10.

While this invention has been described in terms of several preferred embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. A method for testing or calibrating a pressure sensor of a plurality of pressure sensors formed in a wafer, wherein the pressure sensor comprises a pressure-sensitive portion and a signal output, wherein the signal output includes pads, and wherein the pads and the pressure-sensitive portion are arranged on a surface of the wafer, comprising the following steps:
providing a probe card comprising probes with probe tips, wherein the probe card has an upper side and a lower side, wherein the lower side of the probe card is directed towards the surface of the wafer, wherein the probes are arranged on the lower side of the probe card, and wherein a sealing lip surrounding the probe tips is further attached on the lower side of the probe card;
connecting the pressure-sensitive portion of the pressure sensor to the fluid line in a pressure-tight way by contacting the sealing lip with the surface of the wafer, wherein the probe tips are further electrically connected to the pads;
applying a predetermined pressure to the pressure-sensitive portion of the pressure sensor via the fluid line; and
receiving a signal from the signal output of the pressure sensor via the probes of the probe card.

2. The method according to claim 1, wherein the step of applying the predetermined pressure is performed before a step of dicing the wafer.

3. The method according to claim 1, further comprising a step of fixing the wafer on a wafer carrier.

4. The method according to claim 1, further comprising a step of taking the wafer from a rack.

5. The method according to claim 1, further comprising the following steps:
determining a calibration parameter from the predetermined pressure and from the signal received by the signal output of the pressure sensor; and
storing the calibration parameter in storage means of the pressure sensor.

6. The method according to claim 1, further comprising a step of determining whether the pressure sensor is functional, depending on the signal received by the signal output of the pressure sensor.

7. The method according to claim 1, further comprising the following steps:
separating the pressure-sensitive portion of the pressure sensor from the fluid line;
moving the wafer and the fluid line relative to each other by a predetermined distance parallel to the wafer;
connecting a pressure-sensitive portion of another pressure sensor of the plurality of pressure sensors formed in the wafer to the fluid line in a pressure-tight way;
applying the predetermined pressure to the pressure-sensitive portion of the further pressure sensor via the fluid line; and
receiving another signal from a signal output of the further pressure sensor.

8. The method according to claim 1, further comprising the following steps:
setting a temperature of the pressure sensor to a first value before receiving the signal;
setting the temperature of the pressure sensor to a second value after receiving the signal;
applying the predetermined pressure to the pressure-sensitive portion of the pressure sensor via the fluid line after setting the temperature of the pressure sensor to the second value; and
receiving another signal from the signal output of the pressure sensor.

9. The method according to claim 8, wherein the steps of setting the temperature include a respective step of setting a temperature of a wafer carrier.

10. The method according to claim 1, further comprising a step of contacting the signal output of the pressure sensor with a probe card.

11. The method according to claim 1, wherein the probes of the probe card extend such that the probes form an acute angle with the lower side of the probe card.

12. A method for manufacturing a pressure sensor element, comprising the following steps:
providing a wafer having a plurality of pressure sensors, wherein each pressure sensor has a pressure-sensitive portion and a signal output;
applying a method to one of the plurality of pressure sensors, the method being for testing or calibrating a pressure sensor of a plurality of pressure sensors formed in a wafer, wherein the pressure sensor comprises a pressure-sensitive portion and a signal output, wherein the signal output includes pads, and wherein the pads and the pressure-sensitive portion are arranged on a surface of the wafer, the method comprising the following steps;
providing a probe card comprising probes with probe tips, wherein the probe card has an upper side and a lower side, wherein the lower side of the probe card is directed towards the surface of the wafer, wherein the probes are arranged on the lower side of the probe card, and wherein a sealing lip surrounding the probe tips is further attached on the lower side of the probe card;
connecting the pressure-sensitive portion of the pressure sensor to the fluid line in a pressure-tight way by contacting the sealing lip with the surface of the wafer, wherein the probe tips are further electrically connected to the pads;
applying a predetermined pressure to the pressure-sensitive portion of the pressure sensor via the fluid line; and
receiving a signal from the signal output of the pressure sensor via the probes of the probe card;
after applying the method, dicing the wafer to obtain the diced pressure sensor; and
housing the diced pressure: sensor to obtain the pressure sensor element.

13. The method according to claim 12, wherein the step of housing is only performed when the pressure sensor is functional.

14. A device for applying a certain pressure to a pressure sensor of a plurality of pressure sensors formed in a wafer and for receiving a signal from a signal output, having pads, of the pressure sensor, wherein the pressure sensor has a pressure-sensitive portion, and wherein the pads and the pressure-sensitive portion are arranged on a surface of the wafer, comprising;
means for providing a probe card comprising probes with probe tips, wherein the probe card has an upper side and a lower side, wherein the lower side of the probe card is directed towards the surface of the wafer, wherein the probes are arranged on the lower side of the probe card, and wherein a sealing lip surrounding the probe tips is further arranged on the lower side of the probe card;
means for connecting the pressure-sensitive portion to the fluid line provided for supplying the predetermined pressure in a pressure-tight way by contacting the sealing lip with the surface of the wafer, wherein the probe tips are further electrically connected to the pads; and
means for receiving the signal from the signal output of the pressure sensor via the probes of the probe card.

15. The device according to claim 14, wherein the means for receiving is a wafer tester.

16. The device according to claim 14, wherein the sealing lip further surrounds probes of the probe card.

17. The device according to claim 16, wherein the sealing lip further comprises a cap closing an opening of the probe card on the upper side of the probe card in a pressure-tight way.

18. The device according to claim 17, wherein the cap comprises a transparent material.

19. A probe card for testing or calibrating a pressure sensor of a plurality of pressure sensors formed in a wafer, wherein the pressure sensor comprises a pressure-sensitive portion and a signal output, wherein the signal output includes pads, and wherein the pads and the pressure-sensitive portion are arranged on a surface of the wafer, comprising:
a probe card body having an upper side and a lower side, wherein the lower side of the probe card is to be directed towards the upper side of the wafer when the pressure sensor is tested of calibrated;
probes with probe tips arranged on the lower side of the probe card; and
a sealing lip attached to the lower side of the probe card such that it surrounds the probe tips.
